(19) United States
(12) Patent Application Publication
(10) Pub. No.: US 2007/0284589 A1
(43) Pub. Date: Dec. 13, 2007

(54) Light emitting device having increased light output

(76) Inventors: Keat Chuan Ng, Penang (MY); Wei Liam Loo, Penang (MY); Chiau Jin Lee, Penang (MY); Yean Chon Yaw, Penang (MY)

Correspondence Address: Kathy Manke;Avago Technologies Limited, 4380 Ziegler Road, Fort Collins, CO, 80525, US

(21) Appl. No.: 11/449,088

(22) Filed: Jun. 8, 2006

(51) Int. Cl. H01L 33/00; H01L 31/12; H01L 27/15; H01L 29/26

(52) U.S. Cl. 257/79

(57) ABSTRACT

The light intensity emitted from a package is increased by adjusting a portion of the package encapsulant so that light impacting the side walls of the adjusted encapsulant portion will encounter total internal reflection (TIR) with the reflected light directed toward the top surface of the package. The adjusted portion of the package is positioned so that air can be used as the second (exterior) medium with the critical TIR angle being such that light emitted from a light source (such as from an LED die) will be directed primarily so as to escape the package from the top surface as opposed to being scattered internal to the package. In one embodiment, a lower portion of the encapsulant is surrounded by a casing to inwardly direct light from the light source that impacts the side of the encapsulant with an angle less than the critical TIR angle.

### TECHNICAL FIELD

This invention relates to light emitting devices and more particularly to such devices having increased light output.

### BACKGROUND OF THE INVENTION

Light emitting packages are typically constructed using a light source (usually a light emitting diode (LED)) die surrounded by an encapsulant material which in turn is encased within a support. Often the support is a reflector cup made from, for example, polyphthalamide (PPA) or liquid crystal polymer (LCP). Light from the light source passing through the encapsulant impacts the support or reflector cup and is redirected back inside the encapsulant. Some of the light is reflected upward toward the top surface, some of the light is scattered within the encapsulant and some of the light is reflected downward away from the top surface. Thus, a portion of the light is “lost’ within the package itself.

Attempts to increase the light output of such devices have centered on increasing the light intensity of the light source. Such light intensity (Iv) or light flux (Φv) increases for a particular light source are difficult to achieve, take long periods of research and development and are costly. Another method of increasing light output from a light package is to work on the interior quantum efficiency of the light source (i.e. within the light source itself) or to work on the exterior quantum efficiency of the package (i.e. on the encapsulant or the reflector cup). Again, such light increases are difficult to achieve.

In some situations it is possible to install a lens on the device to increase the light output, or at least to focus the light so that it appears brighter in some applications.

### BRIEF SUMMARY OF THE INVENTION

The light intensity emitted from a package is increased by adjusting a portion of the package encapsulant so that light impacting the side walls of the adjusted encapsulant portion will encounter total internal reflection (TIR) with the reflected light directed toward the top surface of the package. The adjusted portion of the package is positioned so that air can be used as the second (exterior) medium with the critical TIR angle being such that light emitted from a light source (such as from an LED die) will be directed primarily so as to escape the package from the top surface as opposed to being scattered internal to the package. In one embodiment, a lower portion of the encapsulant is surrounded by a casing to inwardly direct light from the light source that impacts the side of the encapsulant with an angle less than the critical TIR angle.

### BRIEF DESCRIPTION OF THE DRAWINGS

FIG. 1 shows one embodiment of a light emitting package having a portion of its encapsulant exposed to air;

FIGS. 2A and 2B illustrate critical angle calculations;

FIGS. 3, 4 and 5 show embodiments of light emitting packages having portions of their encapsulant exposed to a medium different from the support structure of the devices;

FIGS. 6A, 6B, 6C and 6D show one embodiment of a method for constructing a light emitting package according to the concepts of this invention; and

FIGS. 7A and 7B show one embodiment for concurrently manufacturing multiple light emitting packages.

FIGS. 8A, 8B, 8C and 8D show one embodiment for concurrently manufacturing multiple light emitting packages.

### DETAILED DESCRIPTION OF THE INVENTION

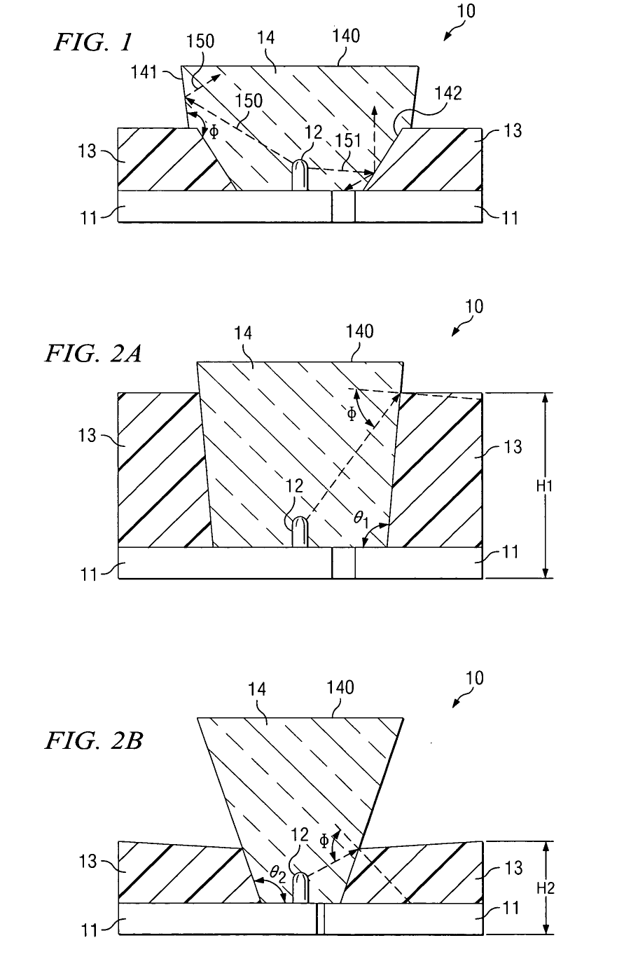

FIG. 1 shows one embodiment of light emitting package 10 arranged for surface mounting via substrate 11, which substrate can be, for example, a lead frame. Mounted on the substrate is a support structure for holding the encapsulant. In one embodiment, this support can be a reflector, such as reflector 13 which can be constructed from, for example, PPA or LCP material. Inside reflector 13 there is mounted one or more light sources 12. This light source can be, for example, an LED chip. Surrounding light source 12 is encapsulant 14, which can be, for example, epoxy resin; silicone (synthetic polymer containing Si—O—Si backbone); or acrylate resin.

A portion of the encapsulant (shown in the embodiment as side walls 141 and top surface 140) extend above side walls 142 of reflector 13. This arrangement then results in encapsulant 14 having at least two regions, with the lower region bounded by the support and the upper region bounded by a medium different from the medium of the support. In the embodiment shown, this upper bounding medium is air.

It is well known that when light passes through one medium into another the light tends to bend at the boundary. When the angle of incidence of the light at the boundary (angle Φ) is greater than a certain value (called the critical angle) then the light, instead of passing out of the medium reflects back into the medium at the same angle Φ. This concept is called total internal reflection (TIR) and the critical angle is dependant upon the medium through which the light is passing as well as the bounding medium. The formula is: sin Φ_{crit}≈nₐᵢᵣ/n_{encapsulant} where nₐᵢᵣ and n_{encapsulant} are the indexes of refraction of the air and encapsulant, respectively.

Unbounded (actually air-bounded in the embodiment of FIG. 1) sidewalls 141 of encapsulant 14 are positioned such that light impacting such unbounded portions will impact with an angle of incidence equal to or greater than the critical angle (Φ_{crit}). The light (characterized by dashed line 150) thereby reflected from the interface of the encapsulant and air is directed toward top surface 140. This reflected light will impact the top surface air interface at an angle less than the critical angle and thus will pass out of the encapsulant through the top surface.

Light from light source 12 (characterized by dashed line 151) impacting reflector (or other encapsulant bounding material) 13 at sides 141 scatters back into the encapsulant. This light also reflects in various directions, with some light going toward top surface 140, while other light is reflected toward the bottom of the package, as shown by the dashed line at the lower right of FIG. 1. It is this scattering and random reflection of light that causes light to be “lost” within the package. Since, as above-discussed, the reflector does not bound the encapsulant all the way to the top of the encapsulant, the amount of light that is lost by reflector scattering is reduced from prior art light emitting packages in which the reflector (or some other medium) bounds the encapsulant from base to top surface.

The TIR effect will be even more significant if the reflector cup is steeper (bigger inclination angle θ) and the refractive index of the encapsulant is higher. For example, refractive index (n) at the emission wavelength changes from a value of n_{epxoy}≈1.5 to nₐᵢᵣ≈1.008. So the critical angle of TIR will be fc≈sin⁻¹ (nₐᵢᵣ/n_{epoxy})≈42°.

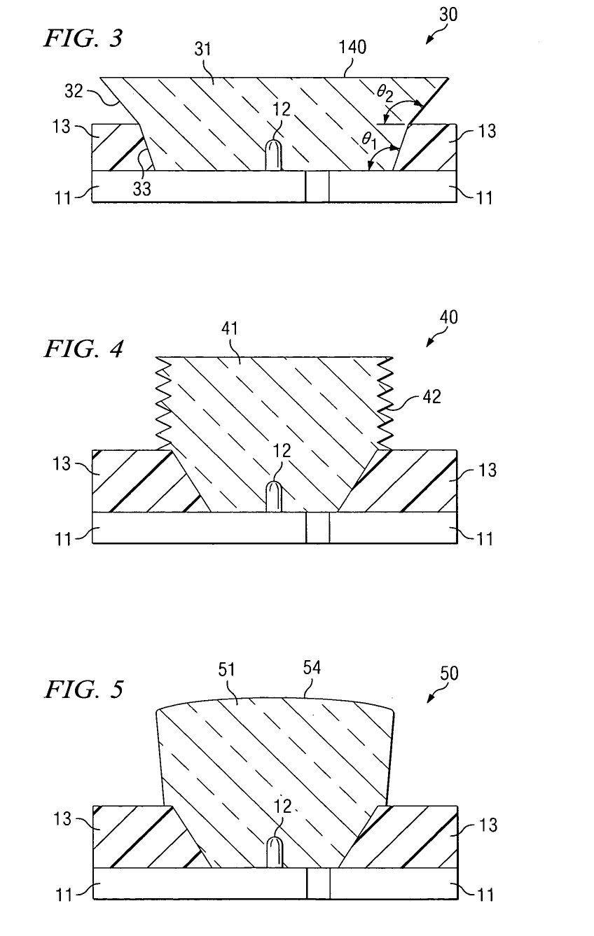

For example, using the same encapsulant, if the inclination angle θ₂>θ₁, then the critical angle Φ where TIR starts to happen will be at a higher portion of the reflector cup where H1>H2 as illustrated in FIG. 2A as shown with respect to FIG. 2B.

Using the concepts discussed herein, it is possible to make a light emitting package with the same or smaller foot print and size, but higher luminous intensity and flux output for a given light source. This can be accomplished by proper calculation and simulation to determine the critical angle of the package that maximizes the light output to the top opening window.

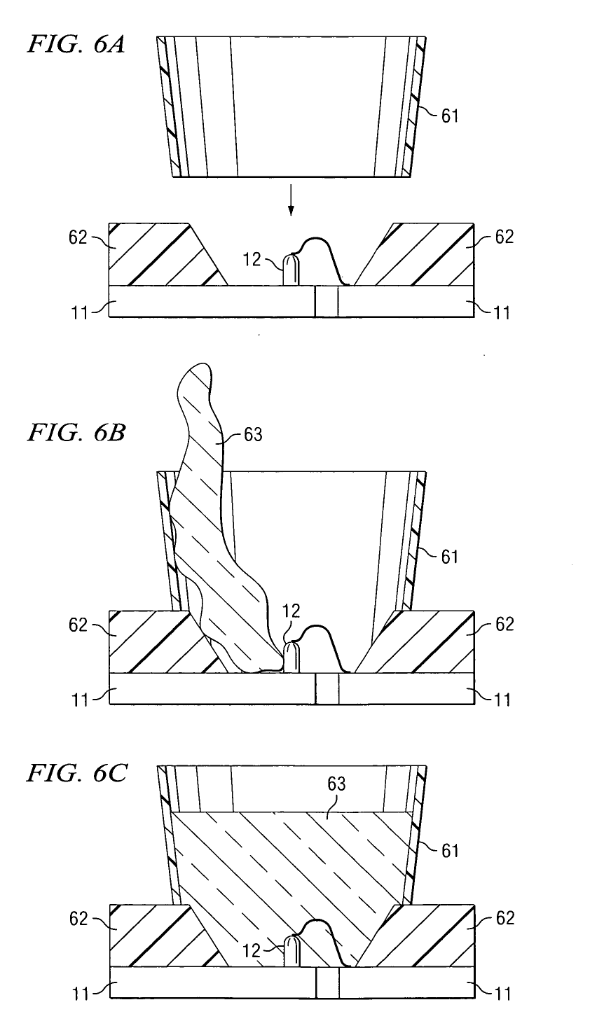

FIG. 3 shows device 30 with die carrier 11 and electrical terminal connection pad area, having air bounded encapsulant 31 with reflector wall 32 having a different inclination angle than that of reflector side wall 33 such that θ₁>θ₂. This arrangement allows side wall 33 to end lower to correct it than it would if the inclination of encapsulant was constant.

FIG. 4 shows embodiment 40 in which air exposed encapsulant side wall 42 is shaped or patterned for different applications and radiation patterns. The amount of light that exits the light package and the direction of such light depends upon where the light from light source 12 impacts side wall 42 of encapsulant 41.

FIG. 5 shows embodiment 50 having a lens type structure 54 as the top surface of encapsulant 51. The lens serves to form the light at a point (or points) outside of the device.

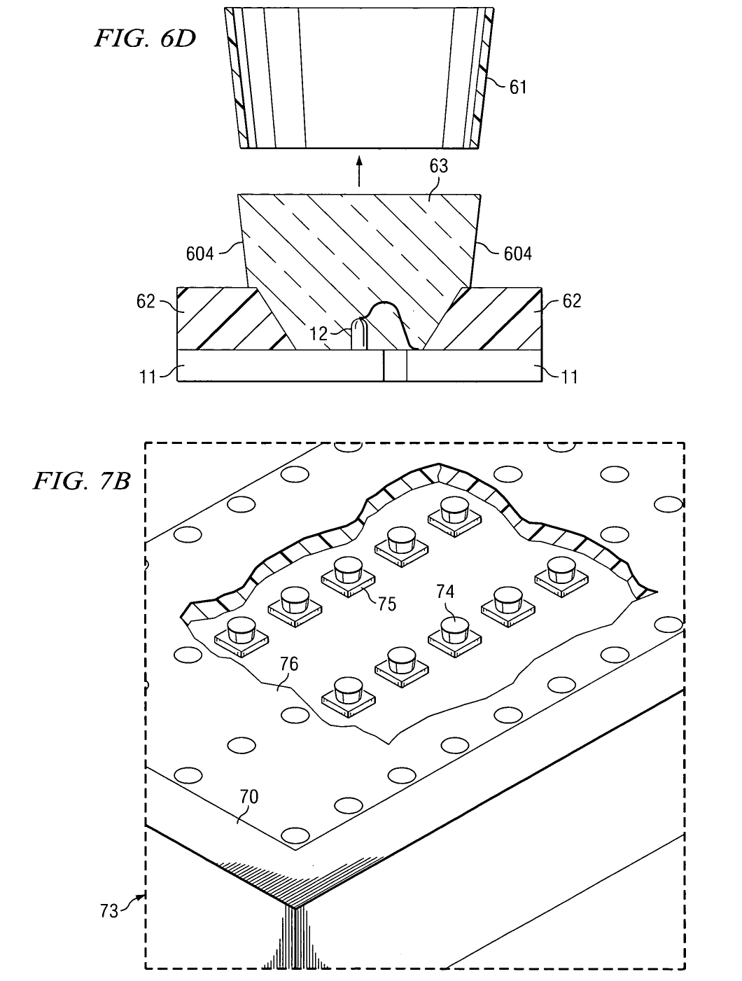

FIGS. 6A-6D show embodiments of package construction in keeping with the concepts discussed above. FIG. 6A shows nozzle tip 61 moving into contact with package 62 until the tip of the nozzle touches the bottom of the package.

FIG. 6B shows encapsulant 63 flowing into the package via nozzle 61 until the desired volume and shape is reached.

FIG. 6C shows nozzle 61 holding encapsulant 63 while the encapsulant is cured, for example, with UV or temperature.

FIG. 6D shows nozzle 61 being removed from the package leaving behind cured encapsulant 63 having sides 604 exposed to air. The nozzle could be a mechanism that could be separated (not shown) during removal from the cured encapsulant to ease the removal process. Nozzle 61 could have the shapes discussed with respect to FIG. 4, if desired.

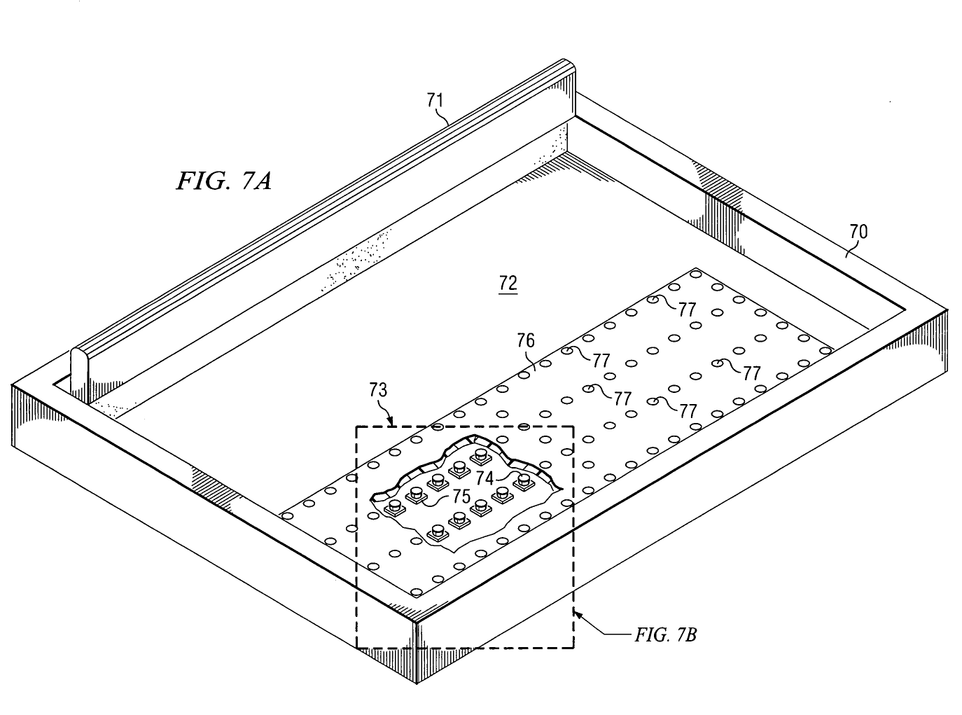

FIG. 7A shows one embodiment 70 of a jig/fixture that is designed to produce protruded encapsulant 74 (FIG. 7B) with a screen printing process using squeegee 71. Finished light packages 74 would appear as shown in FIG. 7B with casing 75 and casting plate 76.

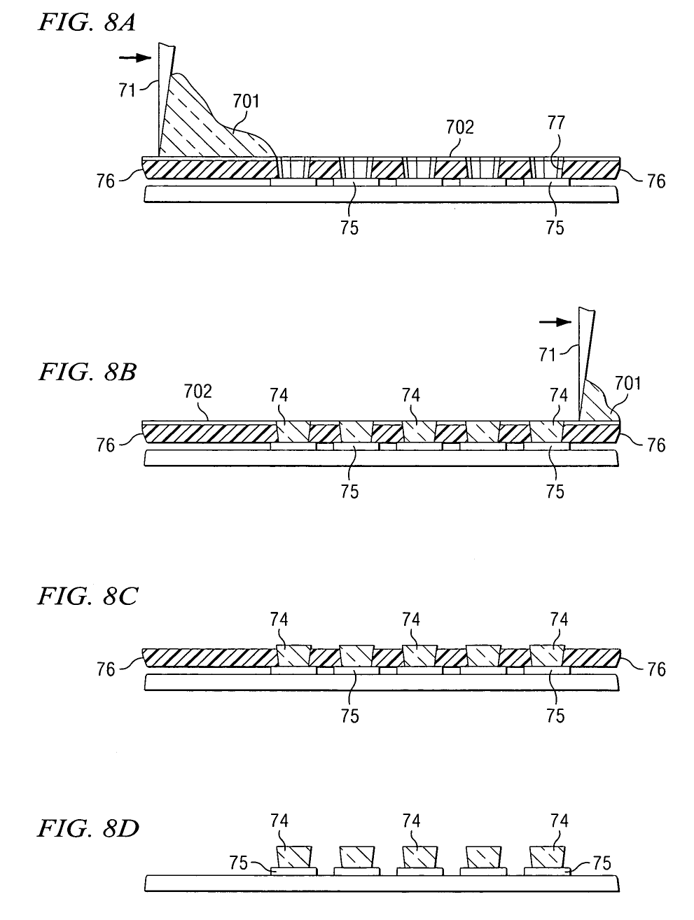

FIGS. 8A-8D show one embodiment for constructing the multiple light packages as illustrated in FIGS. 7A and 7B.

FIG. 8A shows any number of casings 75 placed in a predefined matrix inside screen printing compartment 72 (FIG. 7). Then casting plate 76 consisting of holes in a matrix (which holes coincide with the casing matrix) is placed on top of the casing matrix. On top of casing plate 76 there is placed stencil 702 having holes in a matrix pattern. Then a sufficient amount of liquid encapsulant is placed inside screen printing compartment 72 and moved along by squeegee 71 so that the encapsulant fills the holes as shown in FIG. 8B. As shown in FIG. 8C the stencil is then removed, so that casting plate 76 together with excess encapsulant is removed from the screen printing compartment and sent for curing. FIG. 8D shows the casting plate removed without damage to cured encapsulant 74.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A light emitting package comprising:
a light source;
a light conducting encapsulant surrounding said light source, said encapsulant having a top surface and side surfaces interposed between said top surface and said light source; and
a reflector positioned bounding at least a portion of said side portions of said encapsulant nearest to said light source such that when light from said light source impacts said side portion of said encapsulant bounded by said reflector, said last-mentioned light is reflected inside said encapsulated portion in a plurality of directions and when light from said light source impacts said side portion of said encapsulant not bounded by said reflector, said last-mentioned light is reflected to said top surface of said encapsulant.

2. The light emitting package of claim 1 wherein said light source is an LED die.

3. The light emitting package of claim 1 wherein said light reflected from said non bounded portion of said encapsulant is reflected under total internal reflection (TIR).

4. The light emitting package of claim 3 wherein air bounds said encapsulant between said reflector and said top surface.

5. The light emitting package of claim 1 wherein the limit of the bounding of said encapsulant is at the position on said encapsulant where light from said light source impacts said side of said encapsulant with an angle to achieve total internal reflection (TIR) with a medium different than the medium of said reflector.

6. The light emitting package of claim 5 wherein said medium is air.

7. The light emitting package of claim 1 wherein said unbounded portion of said encapsulant is formed with specific reflection patterns constructed therein.

8. The method of manufacturing a light emitting package, said method comprising:
placing a light emitting source inside a reflector housing; and
pouring within said reflector housing around said light source a light transmission medium, said medium extending from said light source above a top edge of said reflector housing.

9. The method of claim 8 wherein said light source is an LED die.

10. The method of claim 8 wherein said light transmission medium is selected from the list of: epoxy resin, silicone, or acrylate resin.

11. The method of claim 8 wherein said extending is within a temporary support housing, said method further comprising:
curing said light transmission medium within said temporary support housing.

12. The method of claim 11 further comprising:
removing said temporary support housing.

13. The method of claim 11 wherein said temporary support housing has constructed therein surface areas to effectuate specific side surfaces on said cured transmission medium.

14. The method of claim 12 wherein said removing comprises:
separating said temporary support housing into sections.

15. The method of claim 11 wherein said pouring comprises:
a screen printing process for manufacturing a plurality of devices concurrently.

16. An LED device comprising:
an LED die positioned within a support;
light transmission material positioned around said LED die within said support, at least a portion of said transmission material extending beyond an upper surface of said support; and
wherein a top surface of said light transmission material is positioned with respect to sides of said extending portion such that light from said LED die impacting said sides at an angle equal to or greater than the critical angle for total internal reflection to occur with respect to said impacting light will be reflected to said top surface.

17. The LED device of claim 16 further comprising:
a medium bounding said sides, said medium extending from said top surface to said support.

18. The LED device of claim 17 wherein said medium is air.

19. The LED device of claim 18 wherein said light transmission material is selected from the list of: epoxy resin, silicone, or acrylate resin.

20. A light emitting package comprising:
means for emitting light; and
means for supporting light transmission material, said light transmission material communicating light from said light emitting means to a top surface of said light transmission material, said supporting means sized such that at least a portion of said light transmission material extends beyond the boundary of said supporting means.

21. The light emitting package of claim 20 wherein said extended portion is positioned such that light impacting an outer edge of said extended portion will reflect under the conditions imposed by TIR such that said reflected light will emerge from a top surface of said light transmission material.

22. The light emitting package of claim 21 wherein said top surface is shaped as a lens.

23. The light emitting package of claim 21 wherein said extended portion has constructed therein at least one irregularity to effect the direction of light impacting said irregularity.
